(19) United States
(12) Patent Application Publication
(10) Pub. No.: US 2015/0303053 A1
(43) Pub. Date: Oct. 22, 2015

(54) METHOD FOR PRODUCING OZONE GAS-DISSOLVED WATER AND METHOD FOR CLEANING ELECTRONIC MATERIAL

(71) Applicant: KURITA WATER INDUSTRIES LTD., Tokyo (JP)

(72) Inventors: Hiroto TOKOSHIMA, Nakano-ku, Tokyo (JP); Hiroshi MORITA, Nakano-ku, Tokyo (JP)

(73) Assignee: KURITA WATER INDUSTRIES LTD., Nakano-ku, Tokyo (JP)

(21) Appl. No.: 14/439,126

(22) PCT Filed: Oct. 10, 2013
(86) PCT No.: PCT/JP2013/077570

§ 371 Date: Apr. 28, 2015

(30) Foreign Application Priority Data
Nov. 1, 2012 (JP) 2012-241891

(51) Int. Cl. H01L 21/02; C02F 1/78

(52) U.S. Cl. CPC H01L 21/02052; C02F 1/78; C02F 2103/346

(57) ABSTRACT

A method for producing ozone gas-dissolved water includes a process in which a mixed gas of an ozone gas and an oxygen gas and degassed water are supplied to an ozone-dissolving section and the mixed gas is dissolved in the degassed water. The amount of the mixed gas supplied to the ozone-dissolving section is controlled such that the sum of the dissolved oxygen gas concentration of the degassed water and the increment of the dissolved oxygen gas concentration calculated from the amount of the oxygen gas in the mixed gas and the amount of the degassed water on the assumption that ozone in the mixed gas entirely decomposes into oxygen is less than or equal to the saturated solubility of the oxygen gas under conditions using the obtained ozone gas-dissolved water.

### FIELD OF INVENTION

The present invention relates to a method for producing ozone gas-dissolved water preferably used to wet-clean electronic materials (electronic components, electronic members, and the like) for semiconductors, substrates for liquid crystals, and the like and a method for cleaning an electronic material using the ozone gas-dissolved water.

### BACKGROUND ART

Wet cleaning which is a so-called RCA cleaning process has been performed at high temperature using a hydrogen peroxide-based concentrated chemical solution for removing fine particles, organic substances, metals or the like from surfaces of electronic materials such as silicon substrates for semiconductors, glass substrates for flat panel displays, and quartz substrates for photomasks. The RCA cleaning process is effective in removing metal and the like from a surface of an electronic material. The process uses large amounts of high-concentration acid, alkali, and hydrogen peroxide. When these chemicals are contained in wastewater discharged from the process, the wastewater is required to be treated by a treating process such as neutralization or sedimentation. As a large amount of sludge is produced by the wastewater treating process, the RCA cleaning process requires a large amount of rinse water.

Therefore, gas-dissolved water has been used instead of high-concentration chemical solutions. The gas-dissolved water is prepared in such a manner that a specific gas is dissolved in ultra-pure water. A trace amount of a chemical is added to the water when necessary. Cleaning with the gas-dissolved water is less problematic with the persistence of chemicals in articles to be cleaned and has a high cleaning effect; hence, the amount of cleaning water used can be reduced and the amount of rinse water can also be reduced.

Gases for use in gas-dissolved water used as cleaning water for electronic materials are a hydrogen gas, an oxygen gas, an ozone gas, a rare gas, a carbon dioxide gas, and the like. Patent Literature 1 describes a technique for cleaning a substrate with ozone gas-dissolved water.

Ozone gas-dissolved water is used to remove organic substances from surfaces of substrates or to reform the substrate surfaces (to hydrophilize the substrate surfaces) by oxidation effect of ozone. Organic substances and fine particles are both removed from a substrate when the substrate is cleaned by ozone gas-dissolved water to which ultrasonic waves are applied.

For the production of such gas-dissolved water, a method for increasing oxygen dissolution efficiency by degassing water for dissolving gas in advance has been proposed (Patent Literature 2).

### PATENT LITERATURE

Patent Literature 1: Japanese Patent Publication 2000-254598 A

Patent Literature 2: Japanese Patent Publication 2012-186348 A

### SUMMARY OF INVENTION

### Problems to be Solved

An ozone gas is usually supplied in the form of a mixed gas of an oxygen gas and an ozone gas. The mixed gas is composed mainly of oxygen gas. That is, an ozone gas generated by an ozonizer (ozone generator) is usually used as an ozone gas dissolved in water. Ozonizers include a water electrolysis type, a discharge type, an ultraviolet irradiation type, and the like. In either type, an ozone gas is obtained in the form of a mixed gas of an ozone gas and an oxygen gas while the ratio thereof is large or small.

An ozone gas has higher solubility in water than an oxygen gas. In the case where high-concentration ozone gas-dissolved water produced by dissolving a mixed gas of oxygen and ozone in water is supplied to a cleaning process where the ozone gas-dissolved water is used, oxygen generated by the self-decomposition of ozone forms bubbles to cause a reduction of a cleaning effect or breakage of ultrasonic vibrators during ultrasonic cleaning in some cases.

When bubbles adhere to a surface of an article to be cleaned during performing ultrasonic cleaning, then uneven cleaning occurs to reduce a cleaning effect. An ultrasonic vibrator causes cavitation in the presence of bubbles and therefore may possibly be broken. Thus, the number of bubbles in cleaning water needs to be small. In the case of using ozone gas-dissolved water for ultrasonic cleaning, dissolved ozone in water easily decomposes into oxygen, which is likely to form bubbles. This tendency becomes more pronounced as the concentration of a dissolved ozone gas increases, because the amount of an oxygen gas generated by decomposition increases.

It is desired accordingly that the concentration of a dissolved ozone gas is maintained high and the formation of bubbles is suppressed in order to enhance a cleaning effect during cleaning materials with ozone gas-dissolved water.

It is an object of the present invention to provide a method for producing ozone gas-dissolved water in which the concentration of a dissolved ozone gas is high and in which the formation of bubbles by an oxygen gas on site is suppressed.

Furthermore, it is an object of the present invention to provide a method for efficiently cleaning an electronic material using produced ozone gas-dissolved water by avoiding troubles, such as uneven cleaning and mechanical breakage, due to bubbles.

### Solution to Problems

The inventors have made intensive investigations to solve the above problems. As a result, the inventors have found that the above problems are solved by a method in which a mixed gas of an ozone gas and an oxygen gas is dissolved in degassed water such that an oxygen gas-solubility is less than or equal to the saturated solubility of the oxygen gas on site even when all ozone gas (which is contained in the mixed gas of the ozone gas and the oxygen gas) dissolved in degassed water decomposes into an oxygen gas.

The present invention has been accomplished on the basis of such a finding and is as summarized below.

[1] A method for producing ozone gas-dissolved water comprising a process in which a mixed gas of an ozone gas and an oxygen gas and degassed water are supplied to an ozone-dissolving section and the mixed gas is dissolved in the degassed water, wherein the amount of the mixed gas supplied to the ozone-dissolving section is controlled such that the sum of the dissolved oxygen gas concentration of the degassed water and the increment of the dissolved oxygen gas concentration calculated from the amount of the oxygen gas in the mixed gas and the amount of the degassed water on the assumption that ozone in the mixed gas entirely decomposes into oxygen is less than or equal to the saturated solubility of the oxygen gas under conditions using the obtained ozone gas-dissolved water.
[2] The method for producing the ozone gas-dissolved water according to [1], wherein the ozone gas concentration of the mixed gas is 3% by volume or more.
[3] The method for producing the ozone gas-dissolved water according to [1], wherein the mixed gas is obtained by an ozonizer generating an ozone gas from an oxygen gas, and wherein the amount of the mixed gas supplied to the ozone-dissolving section is controlled by adjusting the inlet oxygen gas amount of the ozonizer.
[4] The method for producing the ozone gas-dissolved water according to [1], wherein pH of the ozone gas-dissolved water is neutral or lower, and a gas for suppressing self-decomposition of the dissolved ozone gas in the ozone gas-dissolved water is dissolved in the degassed water or the ozone gas-dissolved water in any one of a stage prior to the ozone-dissolving section, a stage subsequent thereto, and the ozone-dissolving section.
[5] The method for producing the ozone gas-dissolved water according to [1], wherein the dissolved ozone gas concentration of the ozone gas-dissolved water is 1 ppm to 15 ppm.
[6] A method for cleaning an electronic material comprising a process in which the electronic material is cleaned with ozone gas-dissolved water produced by the method for producing the ozone gas-dissolved water according to any one of [1] to [5].
[7] The method for cleaning the electronic material according to [6], wherein the material is cleaned by ultrasonic cleaning using the ozone gas-dissolved water.

### Advantageous Effects of Invention

In the present invention, the amount of a mixed gas supplied to an ozone-dissolving section is controlled such that the sum of the dissolved oxygen gas concentration of degassed water and the increment of the dissolved oxygen gas concentration calculated from the amount of an oxygen gas in the mixed gas and the amount of the degassed water on the assumption that ozone in the mixed gas entirely decomposes into oxygen is less than or equal to the saturated solubility of the oxygen gas under conditions using obtained ozone gas-dissolved water. Therefore, in a site where the ozone gas-dissolved water is used, even if a dissolved ozone gas in the ozone gas-dissolved water entirely decomposes into oxygen, the concentration of oxygen in the ozone gas-dissolved water is less than or equal to the saturated solubility of an oxygen gas under conditions using the same; hence, a dissolved ozone gas in water is prevented from forming bubbles.

Therefore, the formation of bubbles on site is suppressed even when ozone gas-dissolved water has a high ozone gas-concentration. This enables an electronic material to be efficiently cleaned with high-concentration ozone gas-dissolved water having a high cleaning effect by avoiding troubles, such as uneven cleaning and mechanical breakage, due to bubbles.

### BRIEF DESCRIPTION OF DRAWINGS

FIG. 1 is a flow diagram of a supply system for ozone gas-dissolved water that illustrates an example of an embodiment of a method for producing ozone gas-dissolved water and a method for cleaning electronic materials according to the present invention.

FIG. 2 is a flow diagram illustrating a condensed-water discharge mechanism of an ozone-dissolving section according to the present invention.

### DESCRIPTION OF EMBODIMENTS

Embodiments of the present invention are described below in detail.

[Method for Producing Ozone Gas-dissolved Water]

A method for producing ozone gas-dissolved water according to the present invention is characterized in that the ozone gas-dissolved water is produced in such a manner that a mixed gas (hereinafter referred to as “ozone/oxygen mixed gas” in some cases) of an ozone gas and an oxygen gas and degassed water are supplied to an ozone-dissolving section and the mixed gas is dissolved in the supplied water. In the method, the amount of the mixed gas supplied to the ozone-dissolving section is controlled such that the sum of the dissolved oxygen gas concentration of the degassed water and the increment of the dissolved oxygen gas concentration calculated from the amount of the oxygen gas in the mixed gas and the amount of the degassed water on the assumption that ozone in the mixed gas entirely decomposes into oxygen is less than or equal to the saturated solubility of the oxygen gas under conditions using the obtained ozone gas-dissolved water.

In the present invention, the degassed water (hereinafter referred to as “supplied water” in some cases) supplied to the ozone-dissolving section is preferable to have quality suitable for cleaning, and to have pH of neutral or lower in order to maintain the ozone gas concentration of the obtained ozone gas-dissolved water. The supplied water is preferable to have sufficiently low concentration of hydrogen peroxide (preferably 10 ppb or less). Ultra-pure or pure water from which impurities have been removed and which has been degassed is usually used.

The ozone/oxygen mixed gas to be dissolved in the supplied water is preferably an ozone/oxygen mixed gas generated from oxygen gas by an ozonizer. An oxygen gas supplied to the ozonizer (ozone generator) may be one supplied from an oxygen gas bomb. The mixed gas of the ozone gas and the oxygen gas may be obtained in such a manner that the oxygen gas is taken from air in the atmosphere using a PSA (pressure swing adsorption) oxygen enricher and this gas is supplied to the ozonizer. The PSA oxygen enricher and the oxygen gas bomb may be used in combination. It is preferred that an oxygen-enriched gas is produced by a method using the PSA oxygen enricher and an ozone/oxygen mixed gas, the mixed gas is supplied to the ozonizer to convert a portion of an oxygen gas in this gas into an ozone gas, and then the gas comprising the ozone gas thus converted is dissolved in pure water or ultra-pure water. This method is inexpensive and is advantageous in that the manpower to change a gas bomb is unnecessary.

The ozonizer is not particularly limited. A water electrolysis type, an ultraviolet irradiation type, or a discharge type of one can be used. A ozonizer of the discharge type is preferred because a large volume of a high-concentration oxygen gas is readily produced at low cost.

When the ozone gas concentration of the mixed gas supplied to the ozone-dissolving section is high, high-concentration ozone gas-dissolved water can be produced. Therefore, the ozone gas concentration of the mixed gas is preferably 3% by volume (65 g/Nm³) or more and particularly preferably 5% by volume or more. However, the ozone gas concentration of the mixed gas is usually 20% by volume or less depending on specifications of the ozonizer or the like.

In one embodiment, dissolved gas is removed by degassing pure or ultra-pure water supplied to the ozone-dissolving section in advance, and the mixed gas is dissolved therein in an amount less than the amount of the removed dissolved gas, whereby the dissolution of gas can be smoothly performed and the supplied mixed gas can be entirely dissolved in water. Thus, no excess gas is generated. This allows advantages below to be obtained.

(1) The amount of an ozone gas used and the amount of an oxygen gas used as a source thereof are minimized and therefore gas supply cost and ozone-generating electricity can be reduced.
(2) No excess gas is discharged and therefore detoxification treatment is unnecessary; hence, the simplification of an apparatus and cost reduction can be achieved. This allows the cost of producing ozone gas-dissolved water to be reduced.

In contrast, in the case where water supplied to the ozone-dissolving section is not degassed, the efficiency of dissolving an ozone gas in water is usually 50% to 60% and therefore 40% to 50% of an excess ozone gas is emitted; hence, there are problems with the waste of the ozone gas and waste gas treatment.

In the case of degassing water supplied to the ozone-dissolving section, degassing is performed such that the dissolved gas concentration of degassed water is preferably 50% or less, particularly preferably 10% or less, and exceptionally preferably 1% or less of the saturated concentration of dissolved gas at the temperature of the supplied water.

A degassing apparatus for the supplied water is not particularly limited unless the quality of water is impaired. A vacuum degasifier, a membrane degasifier, or the like can be used. A low-pressure membrane degasifier is preferably used because the low-pressure membrane degasifier is compact and is easy in maintenance. In the low-pressure membrane degasifier, a gas phase in a gas-permeable membrane module in which the gas phase and a water phase are separated from each other by a gas-permeable membrane is decompressed, whereby dissolved gas in the water phase is transferred to the gas phase regardless of components thereof.

The degassing apparatus need not necessarily be placed just before the ozone-dissolving section and may be placed upstream thereof.

A material for water supply pipes is not limited unless the quality of water is impaired. Materials, such as CVP (vinyl chloride) and PVDF (polyvinylidene fluoride), having low gas permeability are preferred; however, this does not apply to the case where a high degassing level (for example, a dissolved oxygen gas concentration of 50 ppb or less) is not necessary. In the present invention, no high degassing level is necessary and therefore there are no limitations except water quality conditions.

Pipes for supplying a mixed gas containing an ozone gas and ozone gas-dissolved water are preferably made of a material having sufficient ozone resistance. This material may be PFA (tetrafluoroethylene-perfluoroalkyl vinyl ether copolymer resin), PTFE (polytetrafluoroethylene), or the like.

For the ozone-dissolving section, the following module is preferably used: a gas-dissolving membrane module in which a gas phase and a water phase are separated from each other by a gas-permeable membrane and in which a mixed gas supplied to the gas phase is transferred to the water phase through the gas-permeable membrane and is dissolved therein. The use of such a gas-dissolving membrane module enables gas to be readily dissolved in water and also enables the adjustment and control of the concentration of dissolved gas to be readily performed.

It is important for the ozone-dissolving section, such as the gas-dissolving membrane module, to have sufficient ozone resistance. In usual, one made of PTFE is used.

The ozone-dissolving section is not limited to the gas-dissolving membrane module. The ozone-dissolving section is preferably one capable of increasing dissolution efficiency by ensuring a sufficient time after dissolution and may be one for dissolving by bubbling or one for dissolving using an ejector.

The amount of the ozone/oxygen mixed gas supplied to the ozone-dissolving section, such as the gas-dissolving membrane module, is controlled such that the sum (the total concentration is hereinafter referred to as the “theoretical dissolved oxygen gas concentration of ozone gas-dissolved water” in some cases) of the dissolved oxygen gas concentration of the supplied water supplied to the ozone-dissolving section and the increment of the dissolved oxygen gas concentration of the obtained ozone gas-dissolved water with respect to the dissolved oxygen gas concentration of the supplied water, the dissolved oxygen gas concentration of the obtained ozone gas-dissolved water being calculated from the amount of the oxygen gas in the mixed gas and the amount of the supplied water on the assumption that ozone in the mixed gas entirely decomposes into oxygen, is less than or equal to the saturated solubility (hereinafter referred to as the “saturated oxygen gas concentration” in some cases) of the oxygen gas under conditions using the obtained ozone gas-dissolved water, that is, temperature and pressure conditions on site.

That is, the amount of the mixed gas is controlled such that the following inequality holds:

D_{O2}≧D_{O}+(G/W)

where D_{O2} is the saturated oxygen gas concentration under conditions of use, D_{O} is the dissolved oxygen gas concentration of the supplied water, W is the amount of the supplied water, and G is the amount of the oxygen gas from the mixed gas on the assumption that ozone in the ozone/oxygen mixed gas entirely decomposes into oxygen. (G/W) is the oxygen gas concentration fit in unit with D_{O2} and D_{O}.

The theoretical dissolved oxygen gas concentration of ozone gas-dissolved water may be less than or equal to the saturated oxygen gas concentration and is usually set within the range of 50% to 100% with respect to the saturated oxygen gas concentration.

The dissolved ozone gas concentration of the ozone gas-dissolved water, which is obtained by controlling the amount of the mixed gas supplied to the ozone-dissolving section, is calculated by the following equation (1):

D_{O3}=1.5×D_{O2}×C_{O3} (1)

D_{O3}: the dissolved ozone gas concentration of the ozone gas-dissolved water (ppm)

D_{O2}: the saturated oxygen gas concentration under conditions using the ozone gas-dissolved water (ppm)

C_{O3}: the ozone gas concentration of the ozone/oxygen mixed gas supplied to the ozone-dissolving section (volume percent)

For example, when the ozone gas concentration of the ozone/oxygen mixed gas supplied to the ozone-dissolving section is 7% by volume and the temperature of ozone gas-dissolved water on site is 25° C., the saturated oxygen gas concentration at 25° C. is about 40 ppm and therefore the dissolved ozone gas concentration of the ozone gas-dissolved water is calculated by Equation (1) as follows:

D_{O3}=1.5×D_{O2}×C_{O3}=1.5×40×0.07=4.2 ppm.

In fact, a dissolved ozone gas in water self-decomposes into an oxygen gas and therefore the concentration of the dissolved ozone gas in water is less than the above calculated value.

The dissolved ozone gas concentration of the ozone gas-dissolved water produced in the present invention is not particularly limited but is usually about 1 ppm to 15 ppm and preferably about 2 ppm to 10 ppm.

As is clear from Equation (1), the dissolved ozone gas concentration of the obtained ozone gas-dissolved water depends on the ozone gas concentration of the mixed gas supplied to the ozone-dissolving section. Thus, if about 25% by volume of a high-concentration ozone gas-containing mixed gas can be supplied to the ozone-dissolving section, a higher concentration of ozone gas-dissolved water can be produced.

An ozone gas in water is more likely to self-decompose at higher pH. Therefore, in the present invention, the pH of water may be adjusted to be acidic, for example, a pH of about 2 to 6 in such a manner that an acidic gas or acid reducing the pH of water is supplied to the degassed water supplied to the ozone-dissolving section, the ozone gas-dissolved water obtained from the ozone-dissolving section, or the mixed gas supplied to the ozone-dissolving section or is directly supplied to the ozone-dissolving section and is dissolved in water. In this case, the acidic gas used is preferably a carbon dioxide gas, which has little influence on articles to be cleaned.

[Method for Cleaning Electronic Materials]

In a method for cleaning electronic materials, the electronic materials are cleaned with ozone gas-dissolved water (hereinafter referred to as the “ozone gas-dissolved water according to the present invention” in some cases) produced by the above-mentioned method for producing the ozone gas-dissolved water according to the present invention.

A cleaning function can be enhanced by adding one or more of chemicals such as chelating agents and surfactants to the ozone gas-dissolved water used for cleaning as required. It is important that, for example, a substance, such as alkali or hydrogen peroxide, promoting the decomposition of ozone is not contained.

A cleaning method is not particularly limited. The following methods can be used: any conventionally known methods such as a single wafer cleaning method in which cleaning water to which an ultrasonic wave is applied is sprayed on an article to be cleaned to perform cleaning and a method in which an article to be cleaned is immersed in cleaning water and is cleaned.

In the ultrasonic cleaning, the frequency of an ultrasonic wave used is not particularly limited but is preferably, for example, 10 KHz to 3 MHz as used for common cleaning.

The temperature of cleaning water used for cleaning may range from 10° C. to 90° C. and is preferably determined depending on an article to be cleaned. In general, in the case where fine particles are unlikely to be removed from the article to be cleaned, increasing the temperature of water tends to enhance the removal of the fine particles. In accordance with the ozone gas-dissolved water according to the present invention, even high-concentration ozone gas-dissolved water can suppress the formation of bubbles by an oxygen gas and even room-temperature ozone gas-dissolved water can obtain an excellent cleaning effect due to the high-concentration ozone gas-dissolved water.

When the temperature of water is high, the saturated oxygen gas concentration is high and the high-concentration ozone gas-dissolved water can be stably used. The temperature of the cleaning water is preferably, but is not necessarily limited to, around room temperature, for example, 20° C. to 60° C. from the viewpoint of the protection of an ultrasonic vibrator.

A material for a cleaning tank is not particularly limited. One made of quartz or SUS is usually used. In particular, one made of quartz is preferably used in view of ozone resistance.

Using airtight cleaning tanks and pipes to clean the article to be cleaned with the ozone gas-dissolved water according to the present invention enables the contamination of the cleaning water to be prevented and enables the quality of the cleaning water to be maintained high over a long period of time. In this case, for example, the cleaning water is intensively produced in a single site without separately providing a large number of cleaning machines with apparatuses for producing the cleaning water, whereby it can be supplied through a main pipe and branch pipes in the form of cleaning water with stable quality. In addition, the following system can be formed: a recycling system in which an excess of the cleaning water that is unused in a cleaning machine is returned to a water tank and is fed to the cleaning machine again. The following system may be used: a recovery recycling system in which the cleaning water once used for cleaning is recovered, impurities are removed therefrom so as not to cause problems with next cleaning, the cleaning water is degassed again, a necessary amount of the mixed gas is dissolved therein, and the cleaning water is reused for cleaning. Since a dissolved ozone gas deteriorates wetted members by oxidation, it is preferably introduced into the recycling system after the dissolved ozone gas in water is decomposed by a method such as ultraviolet irradiation.

[System for Supplying Ozone Gas-dissolved Water]

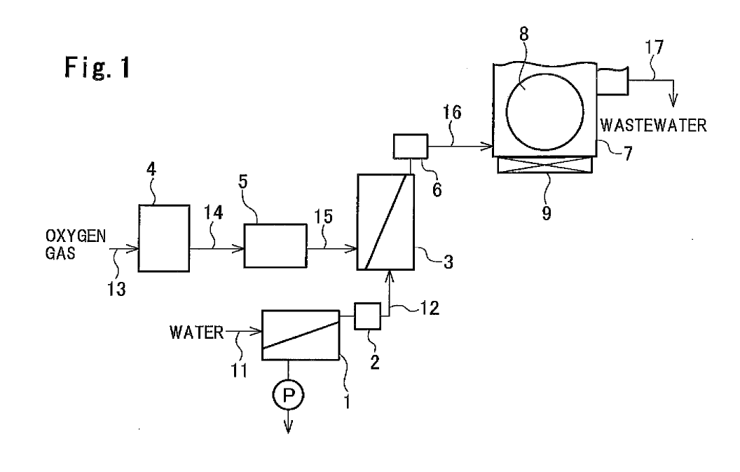

The following method and example are described below with reference to FIG. 1: the method for producing the ozone gas-dissolved water according to the present invention and an example of a system for supplying the ozone gas-dissolved water for the purpose of performing the method for cleaning the electronic material.

The supplied water is supplied to a degassing membrane module 1 through a pipe 11.

The supplied water degassed with the degassing membrane module is measured for flow rate with a flowmeter 2 and is supplied to a gas-dissolving membrane module 3 which is an ozone-dissolving section through a pipe 12. The flowmeter 2 is not particularly limited, is desirably one capable of adjusting the flow rate of an oxygen gas supplied to an ozonizer 5 depending on a flow rate reading, and is preferably one capable of transmitting and outputting the reading.

An oxygen gas from a PSA oxygen enricher or the like is fed through an oxygen supply pipe 13, is adjusted in flow rate with an oxygen flow rate-adjusting mechanism 4, and is then supplied to the ozonizer 5 through a pipe 14. The flow rate of the oxygen gas is calculated from the amount of water that is obtained from a reading of the flowmeter 2 and is controlled to a flow rate less than or equal to the saturated oxygen gas concentration under conditions using the ozone gas-dissolved water. In FIG. 1, in order to supply an oxygen gas amount less than or equal to the saturated oxygen gas concentration to the supplied water sufficiently degassed with the degassing membrane module 1, a dissolution state is maintained such that no bubbles are formed even if an oxygen gas entirely decomposes into an oxygen gas in a site where the ozone gas-dissolved water is used. The oxygen flow rate-adjusting mechanism 4 is not particularly limited and a mass flow controller (MFC) enabling accurate, quick control is preferably used.

An ozone gas generated by the ozonizer 5 is fed to the gas-dissolving membrane module 3, which is the ozone-dissolving section, through an ozone gas supply pipe 15 in the form of the ozone/oxygen mixed gas and is dissolved in the supplied water.

In the gas-dissolving membrane module 3, a saturated solubility or less of the ozone/oxygen mixed gas is dissolved in the degassed supplied water and therefore the ozone/oxygen mixed gas supplied to the gas-dissolving membrane module 3 is entirely dissolved; hence, no excess gas is generated. Therefore, the gas-dissolving membrane module 3 is provided with no system for discharging excess gas.

After being checked for concentration with a dissolved ozone analyzer 6, the ozone gas-dissolved water obtained in the gas-dissolving membrane module 3 is supplied to a cleaning tank 7 through a pipe 16. An article 8 to be cleaned is ultrasonically cleaned with an ultrasonic vibrator 9.

The gas-dissolving membrane module 3 is provided with no system for discharging excess gas as shown in FIG. 1 and therefore is provided with a condensed-water discharge mechanism for discharging condensed-water generated on the primary side (mixed gas supply side) of a membrane.

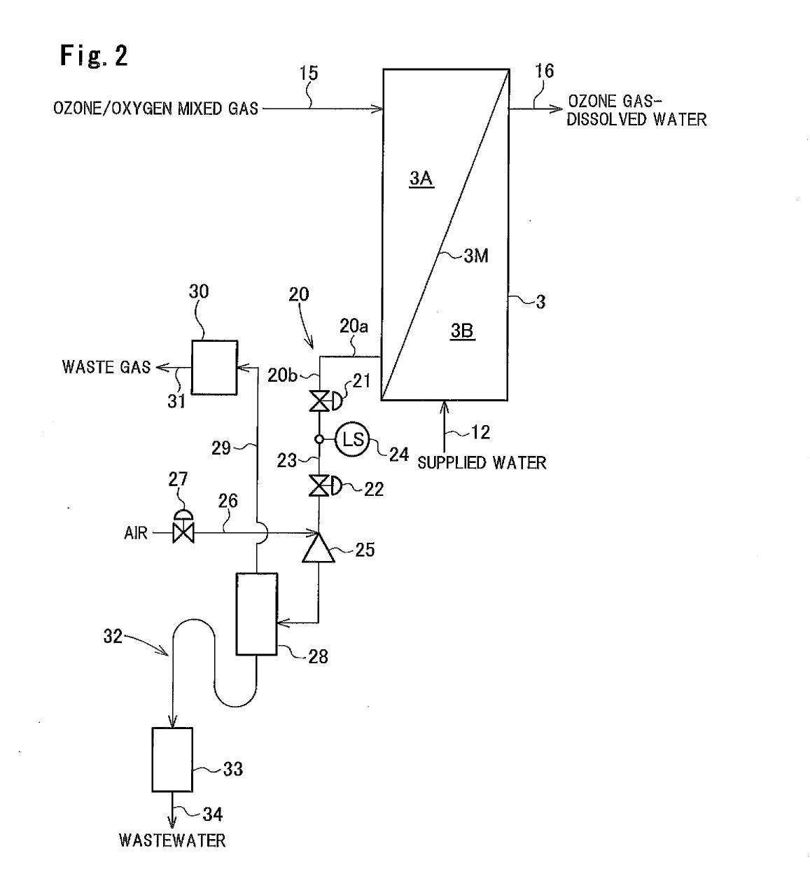

The condensed-water discharge mechanism is described below with reference to FIG. 2.

In FIG. 2, members exhibiting the same function as that of members shown in FIG. 1 are given the same reference numerals.

The inside of a gas-dissolving membrane module 3 is separated into a gas phase chamber (primary side) 3A and a liquid phase chamber (secondary side) 3B by a gas-dissolving membrane 3M. The gas phase chamber 3A is connected to a pipe 15 for supplying the ozone/oxygen mixed gas from an ozonizer 5. The liquid phase chamber 3B is connected to a pipe 12 for supplying the supplied water from a degassing membrane module 1.

A lower portion of the gas phase chamber 3A is connected to a condensed-water discharge pipe 20. The condensed-water discharge pipe 20 includes a horizontal portion 20a which has an end connected to the gas phase chamber 3A and which extends horizontally and a drooping portion 20b drooping from the other end of the horizontal portion 20a. The drooping portion 20b is provided with a first automatic valve 21 and second automatic valve 22 arranged from top to bottom in that order. A portion of the discharge pipe 20 that is interposed between the first automatic valve 21 and the second automatic valve 22 is a storage portion 23. The storage portion 23 is provided with a water-level gauge (LS) 24 for detecting the level of condensed water in the storage portion 23. An ejector 25 is placed under the second automatic valve 22 of the drooping portion 2b. The ejector 25 is connected to a pipe 26 for supplying air as a sweeping gas. The pipe 26 is provided with a third automatic valve 27.

The lower end of the drooping portion 20b is connected to a gas-liquid separator 28. An upper portion of the gas-liquid separator 28 is connected to a pipe 29 for discharging separated gas, an ozone decomposer 30 for decomposing ozone in the separated gas, and a gas discharge pipe 31 for discharging gas produced by decomposing ozone in the form of waste gas. A lower portion of the gas-liquid separator 28 is connected to an activated carbon column 33 through a U-shaped tube 32 for gas trapping and is provided with a wastewater discharge pipe 34 for discharging outflow water from the activated carbon column 33.

In the condensed-water discharge mechanism, condensed water from the gas phase chamber 3A of the gas-dissolving membrane module 3 is stored in the storage portion 23 in such a manner that the first automatic valve 21 is opened and the second automatic valve 22 and the third automatic valve 27 are closed. When the water-level gauge 24 detects that the condensed water is stored in the storage portion 23 to a predetermined level, the first automatic valve 21 is closed and the second automatic valve 22 is opened. Thereafter, air is fed to the ejector 25 through the pipe 26 by closing the third automatic valve 27 and the condensed water in the storage portion 23 is fed to the gas-liquid separator 28 with the ejector 25. In the gas-liquid separator 28, the condensed water (ozone gas-dissolved water) and gases (the ozone/oxygen mixed gas incoming together with the condensed water and a mixed gas emitted from the condensed water) are separated. The gases separated in the gas-liquid separator 28 are discharged from the separated-gas discharge pipe 29. After ozone in the gases is decomposed with the ozone decomposer 30, the gases are discharged outside from a pipe 31. On the other hand, the condensed water separated in the gas-liquid separator 28 is fed to the activated carbon column 33 through the U-shaped tube 32 for gas trapping. After dissolved ozone gas in water is decomposed in the activated carbon column 33, the condensed water is discharged outside from the pipe 34 in the form of wastewater.

After the condensed water in the storage portion 23 is discharged as described above and the water-level gauge 24 detects that the level of water in the storage portion 23 drops to a predetermined level, the second automatic valve 22 is closed, the third automatic valve 27 is opened, and the first automatic valve 21 is then opened, whereby the condensed water from the gas phase chamber 3A of the gas-dissolving membrane module 3 is received and stored in the storage portion 23 again. Thereafter, the same procedure is repeated. The first to third automatic valves 21, 22, and 27 are automatically switched by signals output from the water-level gauge 24 of the storage portion 23.

Pipes and the like of the condensed-water discharge mechanism are made of PFA, PTFE, or the like, which has excellent ozone resistance.

### EXAMPLES

The present invention is further described below in detail with reference to an example and a comparative example.

### Example 1

Ozone gas-dissolved water was produced and an article to be cleaned was cleaned in accordance with a system for supplying the ozone gas-dissolved water as shown in FIG. 1.

Apparatuses used are as described below.

Degassing membrane module: “Liqui-Cel G248” manufactured by Polypore Corporation

Gas-dissolving membrane module: “GNH-01R” manufactured by Japan Gore-Tex Inc.

Ozonizer: “GR-RB” manufactured by Sumitomo Precision Products Co., Ltd.

As supplied water (pure water), water that was degassed with the degassing membrane module 1 so as to have a dissolved oxygen gas concentration of about 10 ppb was supplied to the gas-dissolving membrane module 3. The amount of the supplied water was 10 L/min. The temperature of the supplied water on site was 25° C. The amount of an oxygen gas supplied to the ozonizer 5 was set to 280 NmL/min as the saturated solubility (saturated oxygen gas concentration) of the oxygen gas was 40 ppm at 25° C. That is, the amount of the oxygen gas is calculated to be 280 NmL/min from a saturated oxygen gas concentration of 40 ppm at 25° C. and a supplied water amount of 10 L/min as described below (incidentally, the dissolved oxygen gas concentration of the supplied water was very low and therefore is ignored in calculation).

10×40/32×22.4=280 NmL/min

When the ozone gas concentration of a mixed gas supplied to the gas-dissolving membrane module 3 was 200 g/Nm³ (9.3% by volume), the ozone gas concentration of the ozone gas-dissolved water obtained from the gas-dissolving membrane module 3 was calculated to be 5.58 ppm (=1.5×40×0.093) from Equation (1). In fact, the ozone gas concentration of the ozone gas-dissolved water supplied to a cleaning tank 7 was 4 ppm because of the self-decomposition of a dissolved ozone gas after dissolution. A source oxygen gas was supplied to the ozonizer 4 in such a manner that a carbon dioxide gas was mixed with the source oxygen gas at such a flow rate (50 NmL/min) that it was 10 ppm when the carbon dioxide gas was dissolved in water. The pH of the ozone gas-dissolved water was adjusted to about 5.

The ozone gas-dissolved water produced as described above was used to perform an experiment in cleaning the article to be cleaned.

The following wafer was used as the article to be cleaned: a silicon wafer which was left in a cleanroom for a week and of which surfaces were contaminated with organic substances and fine particles. A cleaning tank used was a batch-type ultrasonic cleaning tank (an ultrasonic frequency of 750 KHz) and the cleaning time was 3 minutes. A cleaning effect was evaluated in such a manner that the number of fine particles, present on the silicon wafer, having a diameter of 0.12 μm or more was measured using a defect inspection system, “WM-1500”, manufactured by Topcon Corporation before and after cleaning and the rate of removal was calculated.

As a result, no bubbles were generated in the cleaning tank or no bubbles were observed on surfaces of the wafer. The rate of removal of the fine particles was 98%.

### Comparative Example 1

In Example 1, pure water that was supplied water was supplied to the gas-dissolving membrane module without being degassed. The supplied water had a dissolved oxygen gas concentration of about 8 ppm and was substantially saturated with gas because about 12 ppm of a dissolved nitrogen gas was dissolved therein. The supplied water was supplied to the gas-dissolving membrane module, excess gas was discharged from the primary side of the gas-dissolving membrane module, and the pressure of discharged gas was adjusted, whereby ozone gas-dissolved water with a dissolved ozone gas concentration of 5.58 ppm was prepared and was supplied to the cleaning tank. It was performed in substantially the same manner as that described in Example 1 except it.

As a result, a large number of bubbles were generated in the cleaning tank and bubbles were observed on surfaces of a wafer. The rate of removal of fine particles was 90%. it is conceivable that in this comparative example, bubbles adhered to surfaces of the wafer and therefore uneven cleaning occurred to reduce the rate of removal of the fine particles.

Each of the ozone gas-dissolved water obtained in Example 1 and the ozone gas-dissolved water obtained in Comparative Example 1 was applied to an ultrasonic nozzle for single wafer cleaning for cleaning wafers one by one. In the ozone gas-dissolved water obtained in Comparative Example 1, an ultrasonic vibrator caused cavitation in the presence of bubbles and therefore was broken. However, in the ozone gas-dissolved water obtained in Example 1, the formation of bubbles was suppressed, no cavitation occurred, and efficient cleaning was performed without breakage.

From this result, it has become clear that the ozone gas-dissolved water produced in the present invention is effective in avoiding the breakage of the ultrasonic vibrator.

The present invention has been described in detail with reference to specific embodiments. It is apparent to those skilled in the art that various modifications can be made without departing from the spirit and scope of the present invention.

This application is based on a Japanese patent application (Japanese Patent Application No. 2012-241891) filed on Nov. 1, 2012, the entirety of which is incorporated herein by reference.

1. A method for producing ozone gas-dissolved water comprising a process in which a mixed gas of an ozone gas and an oxygen gas and degassed water are supplied to an ozone-dissolving section and the mixed gas is dissolved in the degassed water,
wherein the amount of the mixed gas supplied to the ozone-dissolving section is controlled such that the sum of the dissolved oxygen gas concentration of the degassed water and the increment of the dissolved oxygen gas concentration calculated from the amount of the oxygen gas in the mixed gas and the amount of the degassed water on the assumption that ozone in the mixed gas entirely decomposes into oxygen is less than or equal to the saturated solubility of the oxygen gas under conditions using the obtained ozone gas-dissolved water.

2. The method for producing the ozone gas-dissolved water according to claim 1, wherein the ozone gas concentration of the mixed gas is 3% by volume or more.

3. The method for producing the ozone gas-dissolved water according to claim 1, wherein the mixed gas is obtained by an ozonizer generating an ozone gas from an oxygen gas, and wherein the amount of the mixed gas supplied to the ozone-dissolving section is controlled by adjusting the inlet oxygen gas amount of the ozonizer.

4. The method for producing the ozone gas-dissolved water according to claim 1, wherein pH of the ozone gas-dissolved water is neutral or lower, and a gas for suppressing self-decomposition of the dissolved ozone gas in the ozone gas-dissolved water is dissolved in the degassed water or the ozone gas-dissolved water in any one of a stage prior to the ozone-dissolving section, a stage subsequent thereto, and the ozone-dissolving section.

5. The method for producing the ozone gas-dissolved water according to claim 1, wherein the dissolved ozone gas concentration of the ozone gas-dissolved water is 1 ppm to 15 ppm.

6. A method for cleaning an electronic material comprising a process in which the electronic material is cleaned with ozone gas-dissolved water produced by the method for producing the ozone gas-dissolved water according to claim 1.

7. The method for cleaning the electronic material according to claim 6, wherein the material is cleaned by ultrasonic cleaning using the ozone gas-dissolved water.
